(19) United States
(12) Patent Application Publication
(10) Pub. No.: US 2026/0013087 A1
(43) Pub. Date: Jan. 8, 2026

(54) IMMERSION COOLING APPARATUS FOR SERVER PERFORMING LOCAL AUTOMATIC FIRE SUPPRESSION AND LOCAL AUTOMATIC FIRE SUPPRESSION METHOD USING THE SAME

(71) Applicant: SAMSUNG SDS CO., LTD., Seoul (KR)

(72) Inventors: In Woo PARK, Seoul (KR); Sang Hun LEE, Seoul (KR); Taehyun KIM, Seoul (KR); Hank W. BAE, Seoul (KR)

(73) Assignee: SAMSUNG SDS CO., LTD., Seoul (KR)

(21) Appl. No.: 19/262,318

(22) Filed: Jul. 8, 2025

(30) Foreign Application Priority Data
Jul. 8, 2024 (KR) 10-2024-0089940
Oct. 25, 2024 (KR) 10-2024-0147858

(51) Int. Cl. H05K 7/20; A62C 3/16; A62C 37/38

(52) U.S. Cl. CPC H05K 7/20836; A62C 3/16; A62C 37/38; H05K 7/20236; H05K 7/20272; H05K 7/20763

(57) ABSTRACT

The present disclosure relates to an immersion cooling apparatus for a server performing local automatic fire suppression, and a local automatic fire suppression method using the same. An immersion cooling apparatus of an immersion cooling facility for a server of an embodiment of the present disclosure may include: an immersion tank configured to store a coolant and a server immersed in the coolant, the immersion tank including an opening for entry and exit of the server; a cover unit including a cover plate configured to open or close the opening; a heat detection unit configured to detect heat inside the immersion tank and to generate a fire signal; a fire extinguishing gas discharging unit provided in a headspace of the immersion tank and configured to discharge the fire extinguishing gas into the immersion tank; and a fire extinguishing gas storage unit configured to store the fire extinguishing gas and to supply the fire extinguishing gas to the fire extinguishing gas discharging unit when receiving the fire signal.

### CROSS-REFERENCE TO RELATED APPLICATION(S)

This application is based on, and claims priority under 35 U.S.C. 119 to, Korean Patent Applications No. 10-2024-0089940, filed on Jul. 8, 2024, and No. 10-2024-0147858, filed on Oct. 25, 2024, in the Korean Intellectual Property Office, the disclosures of which are hereby incorporated by reference in their entirety.

### BACKGROUND OF THE INVENTION

### 1. Field of the Invention

The present disclosure relates to an immersion cooling apparatus for a server that performs local automatic fire suppression capable of extinguishing an initial fire occurring in an immersion cooling facility for a high-heat-generating server, and a local automatic fire suppression method using the same.

### 2. Description of the Prior Art

An immersion cooling facility refers to an apparatus that directly cools a high-power, high-heat-generation server, such as a GPU, a CPU, or a memory, through immersion cooling by immersing the server in a non-conductive fluid. By utilizing an immersion cooling facility, energy consumption may be reduced, and an environmentally friendly, low-carbon data center system may be constructed.

In general, an immersion cooling facility stores a coolant for cooling in a tank of a predetermined size and is equipped with electrical supply equipment such as a power distribution unit (PDU) capable of supplying power to a server. The immersion coolant used in such a facility has a flash point of about 200 to 250° C., and thus there is a risk of an oil fire or an electrical fire caused by ignition due to an electrical short circuit or abnormal temperature rise in the server.

To suppress such fires, a total flooding-type fire extinguishing system may be installed in a conventional server room. However, when a fire occurs, the activation of the entire fire extinguishing system in the server room may cause extensive damage to all servers, data communication equipment, and the immersion cooling facility located within the server room during the extinguishing process.

In addition, since an immersion cooling facility has a cover, if a fire occurs inside the immersion cooling facility, it may be difficult for a gaseous fire extinguishing agent to penetrate into the immersion cooling facility, making it difficult to achieve effective fire suppression using a total flooding-type fire extinguishing system.

### SUMMARY OF THE INVENTION

The present disclosure provides an immersion cooling apparatus for a server and a local automatic fire suppression method using the same, which are capable of suppressing an initial fire through local automatic fire suppression when a fire occurs inside the immersion cooling apparatus for the server.

The present disclosure provides an immersion cooling apparatus for a server and a local automatic fire suppression method using the same, which are capable of smoothly supplying a fire extinguishing gas to a surface of a coolant through the shape of a cover unit of the immersion cooling apparatus.

The present disclosure provides an immersion cooling apparatus for a server and a local automatic fire suppression method using the same, which include a fire extinguishing gas discharging structure configured to uniformly discharge a fire extinguishing gas into a headspace in the immersion cooling apparatus.

The present disclosure provides an immersion cooling apparatus for a server and a local automatic fire suppression method using the same, which are capable of performing local automatic fire suppression even when a cover of the immersion cooling apparatus is open, by using a fireproof screen.

According to an embodiment of the present disclosure, an immersion cooling apparatus for a server that performs local automatic fire suppression may include: an immersion tank configured to store a coolant and a server immersed in the coolant, the immersion tank including an opening for entry and exit of the server; a cover unit including a cover plate configured to open or close the opening; a heat detection unit configured to detect heat inside the immersion tank and to generate a fire signal; a fire extinguishing gas discharging unit provided in a headspace of the immersion tank and configured to discharge a fire extinguishing gas into the immersion tank; and a fire extinguishing gas storage unit configured to store the fire extinguishing gas and to supply the fire extinguishing gas to the fire extinguishing gas discharging unit when receiving the fire signal.

Here, the cover unit may further include a sealing gasket attached to at least one of the cover plate and the opening, and may be configured to seal the headspace of the immersion tank when closing the opening.

Here, the cover plate may be configured to bulge outward from the immersion tank when closing the opening, so as to guide an air flow that supplies the fire extinguishing gas to a surface of the coolant.

Here, the cross-section of the cover plate may have any of a semicircular shape, an elliptical shape, a rhomboid shape, and a triangular shape.

Here, the cover unit may include: a locking portion configured to fix the cover plate so as to maintain a closed state of the opening; and a locking detection sensor configured to detect contact between the cover plate and the opening in the locking portion and to generate a locking monitoring signal indicating whether the opening is open.

Here, the cover unit may further include an overpressure relief port configured to automatically open the cover plate when a set pressure or higher is applied.

Here, the heat detection unit may include at least two differential heat detectors installed on an inner surface of the cover plate.

Here, the heat detection unit may further include: a flexible conduit provided on an outer surface of the cover plate and connected to the differential heat detectors, the flexible conduit being configured to protect a signal line that transmits the fire signal; and a leakage prevention packing positioned between the differential heat detectors and the inner surface of the cover plate and configured to prevent leakage of the coolant.

Here, the fire extinguishing gas discharging unit may be provided in a column shape extending horizontally along a side surface of the immersion tank, and at least opposite end portions of the fire extinguishing gas discharging unit may be connected to fire extinguishing gas inlet pipes to be supplied with the fire extinguishing gas from the fire extinguishing gas storage unit.

Here, the fire extinguishing gas inlet pipes may be connected between a supply pipe extending from the fire extinguishing gas storage unit and the fire extinguishing gas discharging unit, and may have a downward slope toward the interior of the immersion tank.

Here, the fire extinguishing gas discharging unit may further include a discharge hole on a lower surface thereof to discharge the coolant into the immersion tank when the coolant is introduced.

Here, the fire extinguishing gas discharging unit may include a plurality of discharge nozzles provided at set intervals in the horizontal direction, and the plurality of discharge nozzles may be classified into first nozzles having outlets oriented toward a surface of the coolant and second nozzles having outlets oriented toward a side surface of the immersion tank.

Here, the fire extinguishing gas discharging unit may be configured such that the first nozzles and the second nozzles are alternately arranged in sequence.

According to an embodiment of the present disclosure, the immersion cooling apparatus may further include a screen controller configured to deploy a fireproof screen to block the opening when receiving the fire signal while the cover plate is in the open state.

Here, the screen controller may include: a fireproof screen; a fireproof screen case configured to store the fireproof screen; a motorized opening/closing device configured to pull an opening/closing wire connected to the fireproof screen to deploy the fireproof screen over the opening; and a rail installed in the immersion tank and configured to guide a side portion of the fireproof screen when the fireproof screen is deployed.

Here, the rail may include a slide surface in which a guide groove is formed, and the guide groove is configured such that the side portion of the fireproof screen is inserted and slid therein, and the slide surface may have an upward slope toward the opening.

Here, the side portion may further include a wing portion configured to prevent separation from the guide groove during sliding, and the wing portion may include a sealing gasket in a region that comes into contact with the slide surface within the guide groove.

According to an embodiment of the present disclosure, a local automatic fire suppression method for an immersion cooling facility for a server may include steps of: determining whether an opening of an immersion tank is in a closed state by a cover plate when receiving a fire signal from a heat detection unit or a coolant temperature sensor; spraying a fire extinguishing gas into a headspace of the immersion tank by supplying the fire extinguishing gas into the immersion tank when the opening is determined to be closed; and maintaining the closed state of the opening for a design concentration retention time or longer.

Here, in the step of spraying the fire extinguishing gas, when the opening is determined to be open, a fireproof screen may be deployed in the immersion tank to block the opening, and the fire extinguishing gas may be sprayed into the headspace of the immersion tank.

Here, in the step of determining whether the opening is in the closed state, circulation of the coolant in the immersion tank may be stopped when the fire signal is received.

The solutions to the above-mentioned problems do not enumerate all features of the present disclosure. Various features of the present disclosure, along with associated advantages and effects, may be understood in more detail with reference to the specific embodiments below.

According to an embodiment of the present disclosure, with a local automatic fire suppression apparatus for an immersion cooling facility and a local automatic fire suppression method using the same, it is possible to suppress an initial fire through local automatic fire suppression when a fire occurs inside an immersion cooling apparatus for a server. Accordingly, it is possible to prevent damage to all servers, data communication equipment, and the like in a server room caused by the activation of a fire extinguishing system installed in the server room.

According to an embodiment of the present disclosure, with a local automatic fire suppression apparatus for an immersion cooling facility and a local automatic fire suppression method using the same, it is possible to smoothly supply a fire extinguishing gas to a surface of a coolant through the shape of a cover unit of the immersion cooling apparatus and to implement a fire extinguishing gas discharging structure that allows the gas to be uniformly discharged into the headspace, thereby enabling more efficient fire suppression.

According to an embodiment of the present disclosure, with a local automatic fire suppression apparatus for an immersion cooling facility and a local automatic fire suppression method using the same, it is possible to perform local automatic fire suppression even when the cover of the immersion cooling apparatus is in an open state, by using a fireproof screen.

However, the effects achievable by an immersion cooling apparatus for a server that performs local automatic fire suppression, and a local automatic fire suppression method using the same, according to embodiments of the present disclosure, are not limited to those described above, and other effects not mentioned herein may be clearly understood from the following description by those ordinarily skilled in the art to which the present disclosure pertains.

### BRIEF DESCRIPTION OF THE DRAWINGS

The above and other aspects, features and advantages of the present disclosure will be more apparent from the following detailed description taken in conjunction with the accompanying drawings, in which:

FIG. 1 is a schematic view illustrating the operation of an immersion cooling apparatus for a server according to an embodiment of the present disclosure;

FIG. 2 is a schematic view illustrating the immersion cooling apparatus for a server that performs local automatic fire suppression according to an embodiment of the present disclosure;

FIG. 3 is a schematic cross-sectional view illustrating the immersion cooling apparatus for a server according to an embodiment of the present disclosure;

FIG. 4 is an exemplary view illustrating a design concentration retention time for fire suppression using a fire extinguishing gas in the immersion cooling apparatus for a server according to an embodiment of the present disclosure;

FIGS. 5A, 5B, 5C, and 5D are exemplary views illustrating shapes of a cover unit of the immersion cooling apparatus for a server according to an embodiment of the present disclosure;

FIG. 6A is an exemplary view illustrating a locking unit and a locking detection sensor in the cover unit according to an embodiment of the present disclosure;

FIG. 6B is a cross-sectional view illustrating the locking unit and the locking detection sensor in the cover unit according to an embodiment of the present disclosure;

FIG. 7A is a schematic view illustrating a heat detection unit of the immersion cooling apparatus for a server according to an embodiment of the present disclosure;

FIG. 7B is a schematic view illustrating an inner surface of the cover plate according to an embodiment of the present disclosure;

FIG. 7C is a schematic view illustrating an outer surface of the cover plate according to an embodiment of the present disclosure;

FIG. 8A is a schematic view illustrating a fire extinguishing gas discharging unit of the immersion cooling apparatus for a server according to an embodiment of the present disclosure;

FIG. 8B is a schematic view illustrating a lower surface of the fire extinguishing gas discharging unit of the immersion cooling apparatus for a server according to an embodiment of the present disclosure;

FIG. 9A is a schematic view illustrating discharge nozzles of the immersion cooling apparatus for a server according to an embodiment of the present disclosure;

FIG. 9B is a schematic view illustrating a first nozzle according to an embodiment of the present disclosure;

FIG. 9C is a schematic view illustrating a second nozzle according to an embodiment of the present disclosure;

FIG. 10A is an exemplary view illustrating a state before a fireproof screen is deployed by a screen controller of the immersion cooling apparatus for a server according to an embodiment of the present disclosure;

FIG. 10B is an exemplary view illustrating a state in which the fireproof screen is deployed by the screen controller of the immersion cooling apparatus for a server according to an embodiment of the present disclosure;

FIG. 11A is a cross-sectional view illustrating the structure of the screen controller of the immersion cooling apparatus for a server according to an embodiment of the present disclosure;

FIG. 11B is a front view illustrating the structure of the screen controller of the immersion cooling apparatus for a server according to an embodiment of the present disclosure;

FIG. 12 is a plan view illustrating the structure of the screen controller of the immersion cooling apparatus for a server according to an embodiment of the present disclosure;

FIG. 13A is a cross-sectional view illustrating a rail of the screen controller according to an embodiment of the present disclosure;

FIG. 13B is a cross-sectional view illustrating the operation of the rail when fire extinguishing gas is supplied into the headspace; and

FIG. 14 is a flowchart illustrating a local automatic fire suppression method for the immersion cooling apparatus for a server according to an embodiment of the present disclosure.

### DETAILED DESCRIPTION OF THE EXEMPLARY EMBODIMENTS

Hereinafter, embodiments disclosed herein will be described in detail with reference to the accompanying drawings, and regardless of drawing numbers, the same or similar elements will be assigned the same reference numerals, and redundant descriptions thereof will be omitted.

In addition, in describing the embodiments disclosed herein, when it is determined that detailed descriptions of related known technologies may obscure the gist of the embodiments disclosed herein, the detailed descriptions will be omitted. In addition, it should be understood that the accompanying drawings are only for easy understanding of the embodiments disclosed herein, and that the technical idea disclosed herein is not limited by the accompanying drawings, and includes all changes, equivalents, and substitutes included in the spirit and technical scope of the present disclosure.

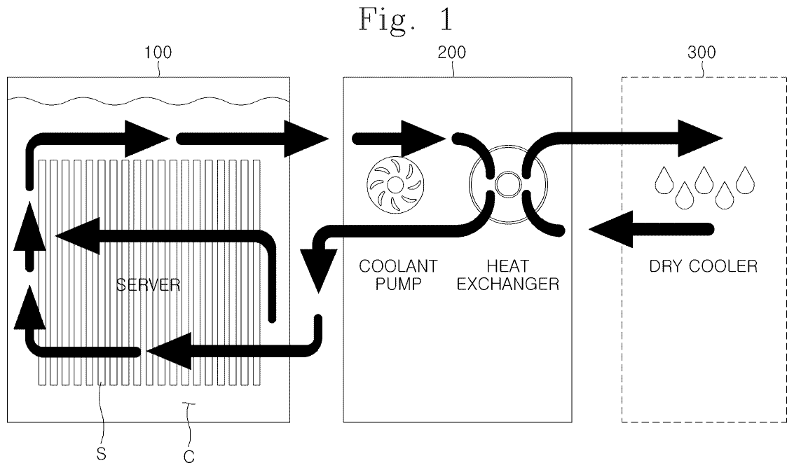

FIG. 1 is a schematic view illustrating the operation of an immersion cooling apparatus for a server according to an embodiment of the present disclosure.

Referring to FIG. 1, an immersion cooling apparatus 100 for a server may directly cool a server S by immersing the server S in a coolant C, which is a non-conductive fluid. Recently, the use of generative artificial intelligence (hereinafter referred to as “Gen AI”), which automatically responds with images, text, and the like in accordance with prompt commands, has been expanding. In order to provide services using Gen AI, it is necessary to train large language models (LLMs) and perform computations based on the trained LLMs. In this case, a dedicated Gen AI server or the like providing high-performance computing may be required, and the Gen AI server or the like providing high-performance computing may consume a large amount of power and generate a high level of heat. Accordingly, in order to cool such a high-power, high-heat-generation server, it is necessary to apply a significantly improved cooling method compared to existing methods. To this end, as illustrated in FIG. 1, an immersion cooling apparatus 100 for a server that utilizes immersion cooling is proposed.

Here, the immersion cooling apparatus 100 for a server may be configured in a rectangular parallelepiped shape, and a server S may be inserted in a vertically standing state along a height direction of the immersion cooling apparatus 100. In addition, a plurality of servers S may be stored at regular intervals along a lengthwise direction of the immersion cooling apparatus 100 for a server.

In this case, a coolant C in the immersion cooling apparatus 100 for a server may absorb heat generated from the server S to cool the server S, and the coolant C heated by the server S may be supplied to an external heat exchanger 200 by a coolant pump. The coolant C may be cooled again by exchanging heat with cooling water in the heat exchanger 200, and the cooling water may release heat to the outside via a dry cooler 300 or the like. As such, the coolant C in the immersion cooling apparatus 100 for a server may be maintained at a low temperature through circulation, and the server S may be maintained within a predetermined temperature range by continuously cooling the server S using the coolant C.

Here, the coolant C may be an environmentally friendly, odorless, non-toxic, non-evaporative, inert, and non-conductive single-phase coolant, and may be a liquid that is electrically and chemically inactive. In addition, the coolant C may be designed not to require replacement during the entire service life (e.g., 15 years) of the immersion cooling apparatus 100. In this case, the flash point of the coolant C may be about 200 to 250° C., and its auto-ignition temperature may be about 350° C.

Meanwhile, in the immersion tank of the immersion cooling apparatus 100 for a server, electrical supply equipment such as a power distribution unit (PDU) for supplying power to the server S may be installed together with the coolant C. Here, a spark may occur due to an electrical short circuit in the electrical supply equipment, or an abnormal temperature rise of the server S may occur. In such a case, the temperature may rise above the flash point of the coolant C, and the coolant C may ignite, leading to an oil fire or an electrical fire.

In general, in a data center or the like where the immersion cooling apparatus 100 is installed, a total flooding-type fire extinguishing system may be installed in each server room to suppress fires. However, when the fire extinguishing system is activated to cover the entire server room when a fire occurs, extensive damage may occur to the server, data communication equipment, the immersion cooling apparatus 100, and the like located in the server room. That is, servers, equipment, or the like that are not actually affected by the fire may also be damaged and rendered unusable.

In addition, the immersion cooling apparatus 100 may include a cover, and even if the fire extinguishing system is activated to suppress the fire, the fire extinguishing agent may fail to penetrate into the immersion cooling apparatus 100 due to the presence of the cover. That is, when a fire occurs inside the immersion cooling apparatus 100, it may be difficult to achieve effective fire suppression using a total flooding-type fire extinguishing system installed in the server room.

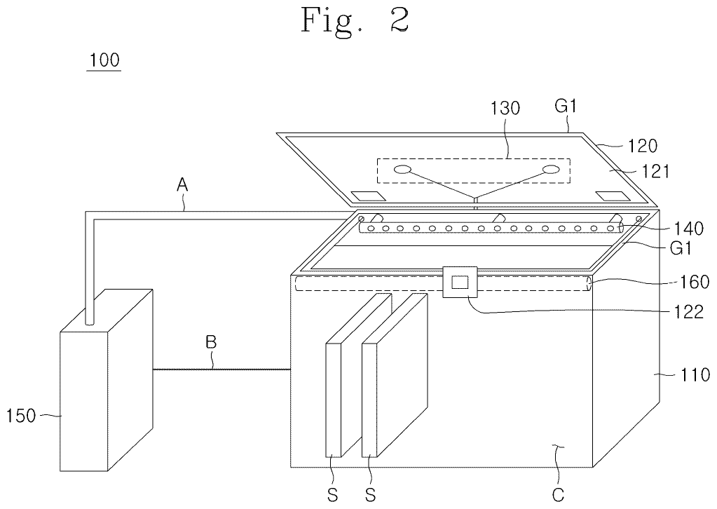

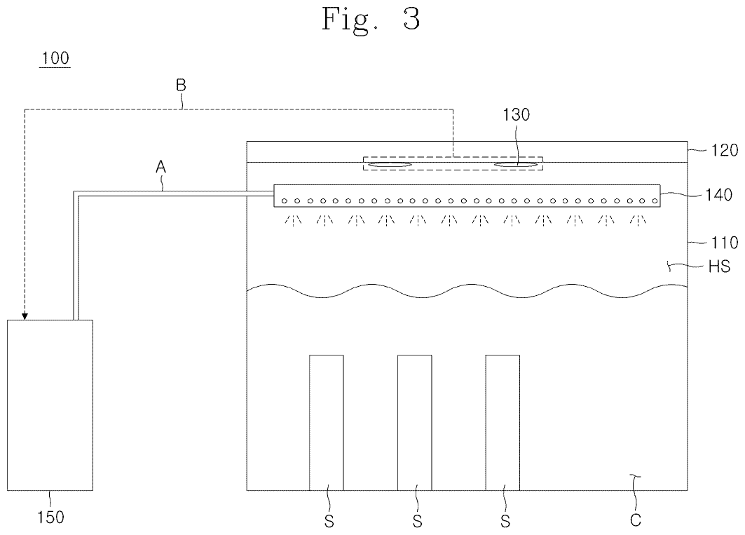

In contrast, according to an embodiment of the present disclosure, when a fire occurs inside the immersion cooling apparatus 100, it is possible to perform local automatic fire suppression that initially extinguishes the fire limited to the immersion cooling apparatus 100 in which the fire has occurred. That is, when an electrical fire or an oil fire occurs inside the immersion cooling apparatus 100, a fire extinguishing gas such as a halogen compound or an inert gas may be sprayed into the immersion cooling apparatus 100 to locally extinguish the fire. Accordingly, when a fire occurs in the immersion cooling apparatus 100, it is possible to obtain effects such as preventing damage caused by the total flooding of fire extinguishing gas throughout the entire server room where the immersion cooling apparatus 100 is installed. Hereinafter, the immersion cooling apparatus 100 for a server according to an embodiment of the present disclosure will be described with reference to FIGS. 2 and 3.

FIGS. 2 and 3 are schematic views each illustrating an immersion cooling apparatus for a server that performs local automatic fire suppression according to an embodiment of the present disclosure.

Referring to FIGS. 2 and 3, an immersion cooling apparatus 100 for a server that performs local automatic fire suppression according an embodiment of the present disclosure may include an immersion tank 110, a cover unit 120, a heat detection unit 130, a fire extinguishing gas discharging unit 140, a fire extinguishing gas storage unit 150, and a screen controller 160.

The immersion tank 110 may store a coolant C and servers S immersed in the coolant C, and may include an opening O for entry and exit of the servers S. That is, a worker or the like may additionally install or remove the servers S inside the immersion tank 110 through the opening O, and perform work such as maintenance. Although the immersion tank 110 may further include components for circulating the coolant C such as a coolant inlet and a coolant outlet, these components are omitted in the drawings for convenience of description.

The coolant C may be filled in the immersion tank 110 to a predetermined depth (e.g., 30 to 35 cm from the opening O to the surface of the coolant C), and the empty space between the surface of the coolant C and the opening O in the immersion tank 110 corresponds to a headspace HS.

The servers S may be high-heat-generation servers such as Gen AI servers, and each server S may be mounted in an immersed state inside the immersion tank 110 using a rack (not illustrated) installed in the immersion tank 110. In some embodiments, a plurality of servers S may be mounted in the immersion tank 110 at respective predetermined unit distances along the lengthwise direction of the immersion tank 110 using the rack. Here, the unit distance may be a height unit (U) of electronic communication equipment as defined by the International Electrotechnical Commission (IEC), where 1U=44.45 mm (1.750 inches). For example, servers S having a height of 24U to 84U may be installed in the immersion tank 110. In this case, the immersion tank 110 may have a rectangular parallelepiped shape that is elongated in the lengthwise direction to accommodate the installation of the servers S.

The cover unit 120 may include a cover plate 121 configured to open or close the opening O. The cover plate 121 may be connected to the immersion tank 110 via a hinge or the like, and the opening O of the immersion tank 110 may be opened by lifting the cover plate 121 or closed by lowering the cover plate 121.

At this time, as illustrated in FIG. 2, a sealing gasket G1 may be attached to the cover plate 121 or the opening O. That is, when the cover plate 121 closes the opening O, the headspace HS of the immersion tank 110 may be sealed by the sealing gasket G1. In this case, the cover plate 121 may not only serve to prevent the coolant C from overflowing from the immersion tank 110, but may also perform a sealing function to prevent the fire extinguishing gas sprayed into the headspace HS from escaping from the headspace HS. Here, the sealing gasket G1 may be made of a material that does not deform or discolor over time, and may be made of a material that does not react with the coolant C.

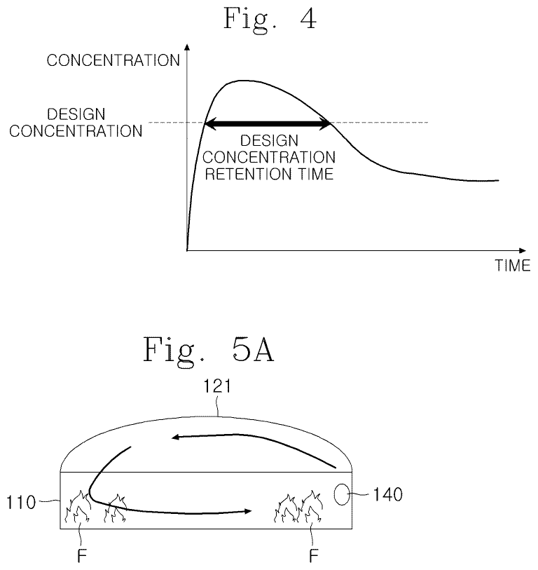

When a fire occurs in the coolant C inside the immersion cooling apparatus 100, a fire extinguishing gas may be supplied into the headspace HS. As illustrated in FIG. 4, in order to suppress the fire in the coolant C, it is necessary to maintain a design concentration of the fire extinguishing gas in the headspace HS for a predetermined design concentration retention time (soaking time). Here, when the cover plate 121 and the opening O further include the sealing gasket G1, the headspace HS may be sealed, which may make it easier to maintain the concentration of the fire extinguishing gas in the headspace HS at the design concentration for the design concentration retention time.

Meanwhile, a fire that occurs in the immersion cooling apparatus 100 corresponds to a liquid surface fire occurring on the surface of the coolant C. That is, due to the ignition characteristics of a fire, the fire occurs in an area above the liquid surface, and therefore, for effective fire suppression, it is necessary for the fire extinguishing agent to reach the area above the liquid surface.

Here, when the cover plate 121 has a flat plate shape, it may be insufficient to reflect the fire extinguishing gas to the area above the liquid surface when the gas is discharged toward the cover plate 121. That is, although the fire extinguishing gas is designed to be discharged to the area above the liquid surface, some of the fire extinguishing gas may be sprayed toward the cover plate 121. Therefore, it is necessary to design the shape of the cover plate 121 so as to enable the fire extinguishing gas to be effectively reflected to the area above the liquid surface where the fire has occurred.

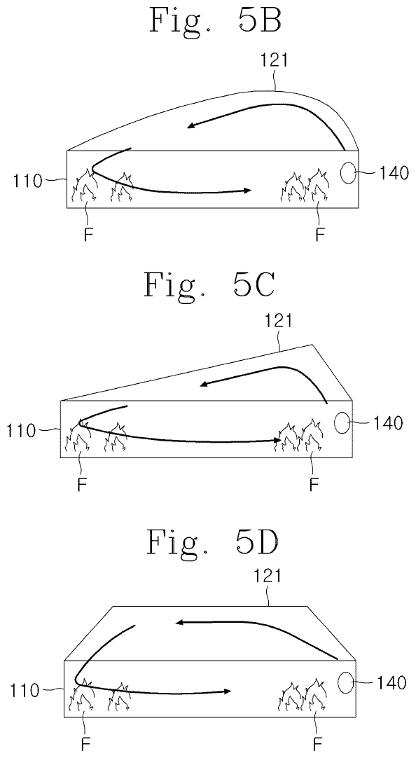

To this end, the cover plate 121 may be implemented in a shape that bulges outward from the immersion tank 110 when closing the opening O, so as to guide an airflow that supplies the fire extinguishing gas to the surface of the coolant C. Specifically, as illustrated in FIG. 5A to FIG. 5D, the cover plate 121 may have a cross-sectional shape such as a semicircular shape, an elliptical shape, a rhomboid shape, or a triangular shape. That is, referring to FIG. 5A, the fire extinguishing gas may be discharged through the fire extinguishing gas discharging unit 140, and in this case, the fire extinguishing gas may circulate along the rounded semicircular cover plate 121 to be supplied to the area above the liquid surface where the fire F has occurred. Likewise, even when the cover plate 121 has an elliptical shape as illustrated in FIG. 5B, an inclined triangular shape as illustrated in FIG. 5C, or a rhomboid shape as illustrated in FIG. 5D, the fire extinguishing gas may circulate along the shape of the cover plate 121 to be supplied to the area above the liquid surface. However, FIGS. 5A to 5D merely illustrate examples of the shape of the cover plate 121, and the cover plate 121 may be implemented in any shape that allows the fire extinguishing gas to be smoothly supplied to the area above the liquid surface.

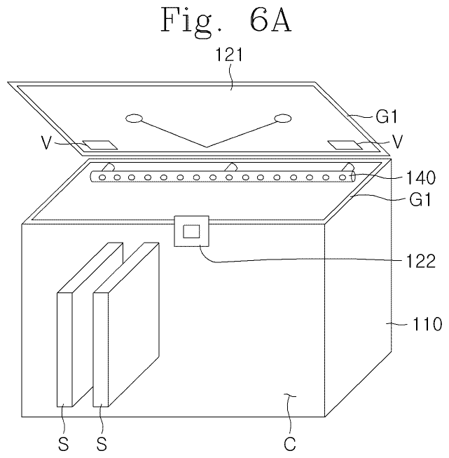

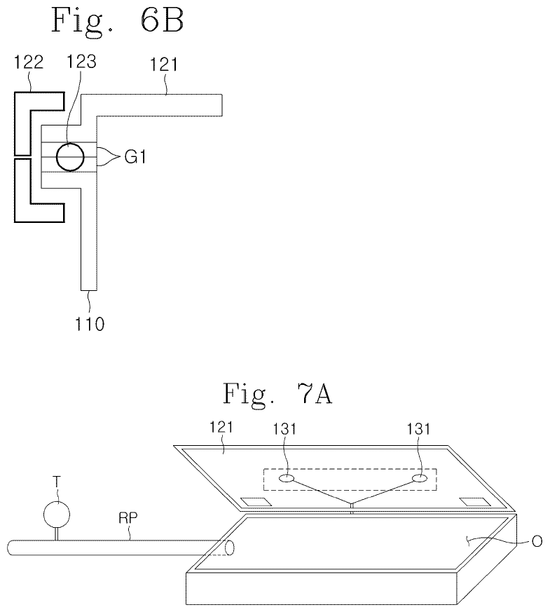

In addition, as illustrated in FIGS. 6A and 6B, the cover unit 120 may further include a locking unit 122 and a locking detection sensor 123. The locking unit 122 fixes the cover plate 121 to maintain the closed state of the opening O. For example, the locking unit 122 may be implemented such that a clip included in the locking unit 122 engages with a latch of the immersion tank 110. However, without being limited thereto, the locking unit 122 may be implemented in various ways depending on the embodiment.

In addition, the locking detection sensor 123 may detect contact between the cover plate 121 and the opening O within the locking unit 122 and may generate a locking monitoring signal indicating whether the opening O is open. Through the locking monitoring signal of the locking detection sensor 123, it is possible to determine whether the opening O is currently in an open state or in a closed state. When a fire occurs, the open/closed state of the opening O may first be determined, and then each control may be performed differently accordingly. The locking detection sensor 123 may be implemented in various forms, such as a magnetic sensor, a micro switch, an optical sensor, or a pressure sensor.

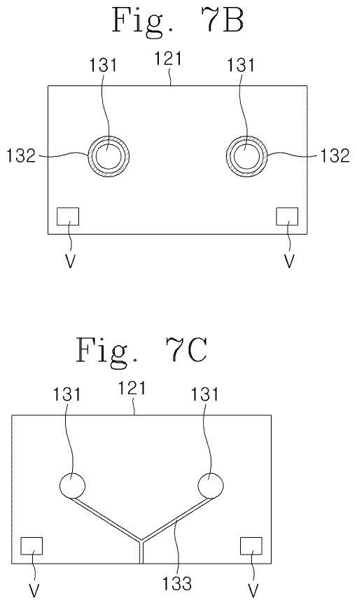

In addition, referring to FIGS. 7A to 7C, the cover unit 120 may further include overpressure relief ports V on the cover plate 121. The overpressure relief ports V may be designed to automatically open when a preset pressure is exceeded. When the fire extinguishing gas is discharged in a state in which the headspace HS is sealed by the cover unit 120, the internal pressure of the headspace HS may rapidly increase. When the internal pressure of the headspace HS becomes excessively high, problems such as the explosion of the cover unit 120 of the immersion cooling apparatus 100 may occur. Therefore, the overpressure relief ports V may be used to discharge the fire extinguishing gas or the like to the outside when the pressure exceeds the preset value so as to adjust the internal pressure of the headspace HS.

The heat detection unit 130 may detect heat inside the immersion tank 110 and generate a fire signal. As illustrated in FIG. 7A, the heat detection unit 130 may include at least two differential heat detectors (rate-of-rise type detectors) installed on the inner surface of the cover plate. That is, the heat detection unit 130 may not detect a fire based on an absolute temperature value, but may determine whether a fire has occurred based on the rate of temperature rise.

Specifically, the differential heat detectors 131 are installed on the inner surface of the cover plate, and may thus detect the temperature of the coolant C transmitted through the headspace HS. In general, the temperature of the coolant C is maintained within a predetermined range, but when a fire occurs, the temperature of the coolant C may rapidly rise. Accordingly, by using the differential heat detectors 131, a rapid increase in the temperature of the coolant C may be detected. Through this, a fire in the immersion tank 110 may be detected and a fire signal may be generated.

In addition, when the heat detection unit 130 includes two or more differential heat detectors 131, the heat detection unit 130 may generate a fire signal only when all of the differential heat detectors 131 determine that a fire has occurred.

Furthermore, as illustrated in FIG. 7A, the heat detection unit 130 may further include a coolant temperature sensor T, such as a temperature sensor installed on a transfer pipe RP connected to a coolant outlet, in addition to the differential heat detectors 131 installed on the cover plate 121. Here, the coolant temperature sensor T may measure the temperature of the coolant C in the transfer pipe RP, and when the measured temperature of the coolant C exceeds a preset temperature, the coolant temperature sensor may determine that a fire has occurred. For example, when the temperature of the coolant C measured by the coolant temperature sensor T reaches an auto-ignition temperature, the heat detection unit 130 may generate a fire signal. That is, even if no fire has occurred, when the auto-ignition temperature is reached, there is a very high possibility that an actual fire will occur. Therefore, even before a fire occurs, a fire signal may be generated to take preemptive measures such as supplying the fire extinguishing gas.

Meanwhile, referring to FIGS. 7B and 7C, the heat detection unit 130 may further include leakage prevention packings 132 and flexible conduits 133. Here, FIG. 7B corresponds to the inner surface of the cover plate 121, and FIG. 7C corresponds to the outer surface of the cover plate 121.

The leakage prevention packings 132 may be positioned between the respective differential heat detectors 131 and the inner surface of the cover plate 121. The differential heat detectors 131, which need to measure the temperature inside the immersion cooling apparatus 100, are installed on the inner surface of the cover plate 121. In this case, through-holes or the like may be formed in the cover plate 121 for the installation of the differential heat detectors 131. Here, because the through-holes may cause the coolant C to leak to the outside of the cover unit 120, the leakage prevention packings 132 may be further provided between the differential heat detectors 131 and the inner surface of the cover plate 121 so as to prevent leakage of the coolant C. Here, the leakage prevention packings 132 may be made of rubber material and may have oil resistance so as not to dissolve or degrade in an oil-based substance such as the coolant C.

The flexible conduits 133 may be located on the outer surface of the cover plate 121 and may be configured to protect signal lines that are connected to the differential heat detectors 131 and transmit fire signals. That is, in order to prevent the signal lines for transmitting the fire signals from being damaged, the flexible conduits 133, which may be made of a material such as polyvinyl chloride (PVC), may be further provided on the outer surface of the cover plate 121.

The fire extinguishing gas discharging unit 140 may be installed in the headspace HS of the immersion tank 110 and may discharge a fire extinguishing gas into the immersion tank 110 when a fire occurs. That is, the fire extinguishing gas discharging unit 140 may supply the fire extinguishing gas into the headspace HS, and may allow the fire extinguishing gas to be maintained in the headspace HS at a predetermined concentration (e.g., a design concentration) for a predetermined period of time (e.g., a design concentration retention time) or longer.

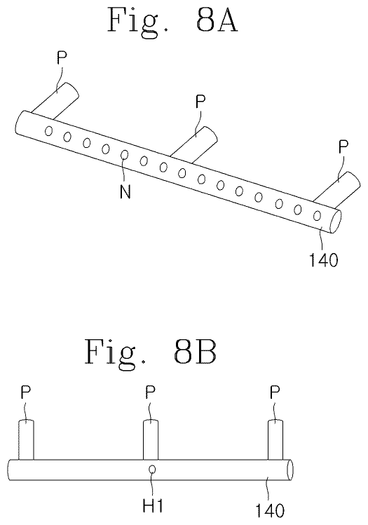

As illustrated in FIG. 8A, the fire extinguishing gas discharging unit 140 may be provided in a column shape extending horizontally along a side surface of the immersion tank 110, and a plurality of nozzles N may be provided at regular intervals at a lower end portion thereof so that the fire extinguishing gas is evenly discharged onto the surface of the coolant C along the horizontal direction. That is, the fire extinguishing gas sprayed from the nozzles N may evenly cover the surface of the coolant C. In addition, as illustrated in FIG. 8A, in order to prevent the discharge pressure of the fire extinguishing gas from being concentrated on a single nozzle N, gas inlet pipes P may be connected to opposite end portions and a central portion of the fire extinguishing gas discharging unit 140.

The fire extinguishing gas inlet pipes P connect the supply pipe A extending from the fire extinguishing gas storage unit 150 to the fire extinguishing gas discharging unit 140. The fire extinguishing gas inlet pipes P may have a downward slope (e.g., 15 to 30 degrees) toward the interior of the immersion tank 110. That is, the fire extinguishing gas inlet pipes P have a gradient sloping toward the immersion tank 110 and may thus prevent the fire extinguishing gas or the coolant C from flowing in the reverse direction.

In addition, as illustrated in FIG. 8B, the fire extinguishing gas discharging unit 140 may further include a discharge hole H on its lower surface, so that when the coolant C flows into the fire extinguishing gas discharging unit 140, the coolant C may be discharged back into the immersion tank 110. For example, when a submerged server S in the immersion tank 110 is replaced or maintained, the coolant C may flow into the fire extinguishing gas discharging unit 140. In this case, the coolant C, which may become an obstacle to the discharge of the fire extinguishing gas, may be discharged through the discharge hole H.

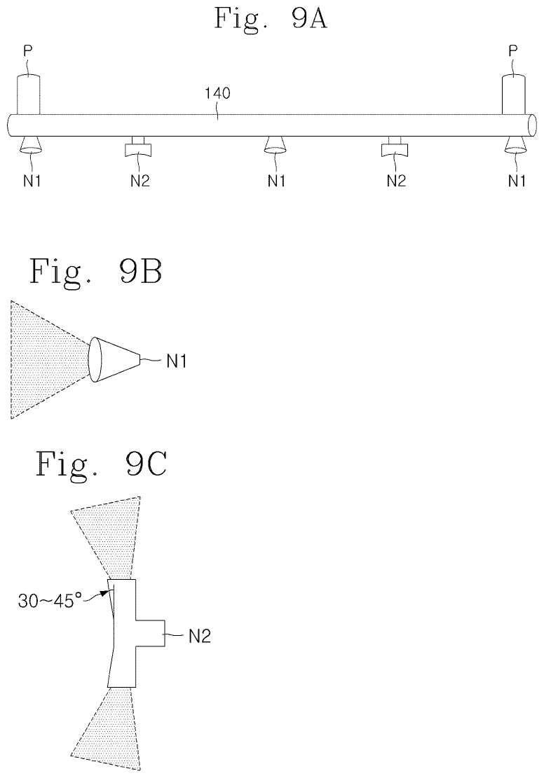

In addition, as illustrated in FIG. 9A, the fire extinguishing gas discharging unit 140 may further include discharge nozzles N1 and N2, which may be installed on the fire extinguishing gas discharging unit 140 at set intervals in the horizontal direction. Here, the discharge nozzles N1 and N2 may be classified into first nozzles N1 and second nozzles N2, and as illustrated in FIG. 9A, the first nozzles N1 and the second nozzles N2 may be alternately arranged in sequence on the fire extinguishing gas discharging unit 140.

Specifically, as illustrated in FIG. 9B, the first nozzles N1 may be configured such that their outlets are oriented toward the surface of the coolant C, and as illustrated in FIG. 9C, the second nozzles N2 may be configured such that their outlets are oriented toward a side surface of the immersion tank 110. Since the fire extinguishing gas needs to fill the headspace HS to at least a predetermined concentration, it is necessary for the fire extinguishing gas to be evenly discharged not only toward the surface of the coolant C but also toward the side surface of the immersion tank 110. Accordingly, by including the first nozzles N1 and the second nozzles N2 in the fire extinguishing gas discharging unit 140, the interior of the headspace HS may be evenly filled with the fire extinguishing gas when the fire extinguishing gas is discharged.

The fire extinguishing gas storage unit 150 may store the fire extinguishing gas in a storage container or the like, and may supply the fire extinguishing gas to the fire extinguishing gas discharging unit 140 when receiving a fire signal. As illustrated in FIGS. 2 and 3, the fire extinguishing gas storage unit 150 may be connected to the heat detection unit 130 via a signal line B, and when the fire signal is received through the signal line B, the fire extinguishing storage unit 150 may determine that a fire has occurred in the corresponding immersion tank 110. In this case, the fire extinguishing gas storage unit 150 may supply the stored fire extinguishing gas to the fire extinguishing gas discharging unit 140 in the immersion tank 110 through the supply pipe A. In some embodiments, the fire extinguishing gas storage unit 150 may receive the fire signal from the coolant temperature sensor T provided in the transfer pipe RP, and may supply the fire extinguishing gas to the fire extinguishing gas discharging unit 140 in response to the received fire signal.

Specifically, when the fire signal is received, the fire extinguishing gas storage unit 150 may release the fire extinguishing gas from the storage container by triggering a solenoid valve and discharging an actuation cylinder according to an operation sequence. The discharged fire extinguishing gas may be uniformly sprayed into the headspace HS of the immersion cooling apparatus 100 through the supply pipe A and the fire extinguishing gas discharging unit 140. In addition, the fire extinguishing gas storage unit 150 may perform control, such as closing and blocking a valve for the coolant circulation pipe, to prevent the spread of fire heat through the circulation of the coolant C.

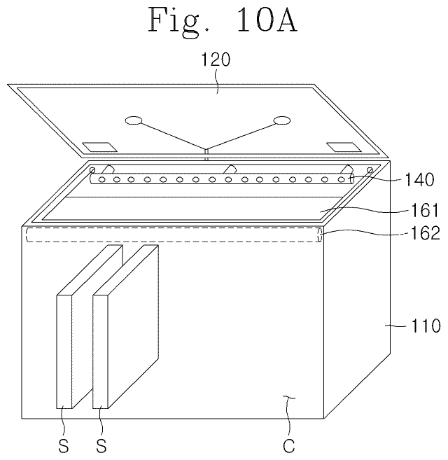

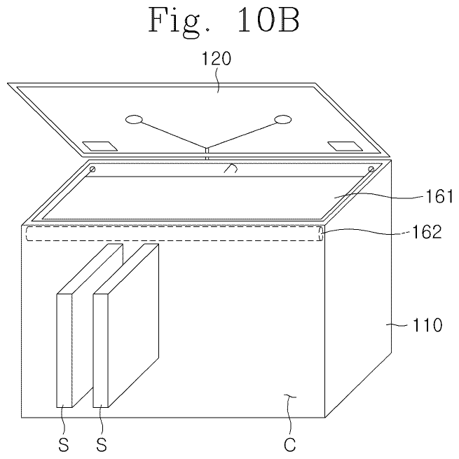

The screen controller 160 may deploy a fireproof screen 161 to block the opening O of the immersion tank 110 when receiving a fire signal while the cover plate 120 is in an open state. That is, as illustrated in FIG. 10A, the screen controller 160 may begin extracting the fireproof screen 161 stored in a fireproof screen case 162, and as illustrated in FIG. 10B, may deploy the fireproof screen 161 to block the opening O.

When a fire occurs in the coolant C while the immersion tank 110 is in an open state, it may be difficult to suppress the fire because the design concentration may not be maintained even if the fire extinguishing gas is supplied to the headspace HS. Accordingly, when the screen controller 160 is further provided, the screen controller may be implemented to block the opening O with the fireproof screen 161 when a fire occurs while the opening O is in an open state. In this case, it may be possible to prevent the spread of fire with the fireproof screen 161, and to maintain the design concentration of the fire extinguishing gas.

The screen controller 160 may be interlinked with the fire extinguishing gas storage unit 150. When the fire signal is received and the cover plate 121 is in an open state, the fire extinguishing gas storage unit 150 may request the screen controller 160 to deploy the fireproof screen 161. Here, the fire extinguishing gas storage unit 150 may be connected to a locking detection sensor 122 via a signal line, and may control the operation of the screen controller 160 using the locking monitoring signal received from the locking detection sensor 122 and the fire signal received from the heat detection unit 130.

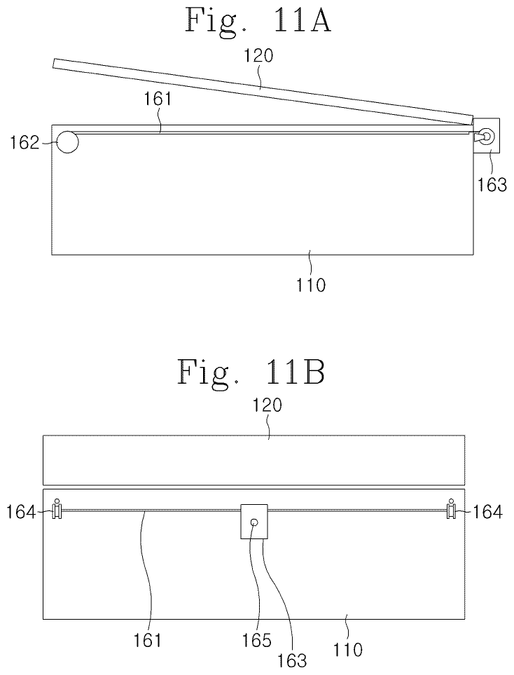

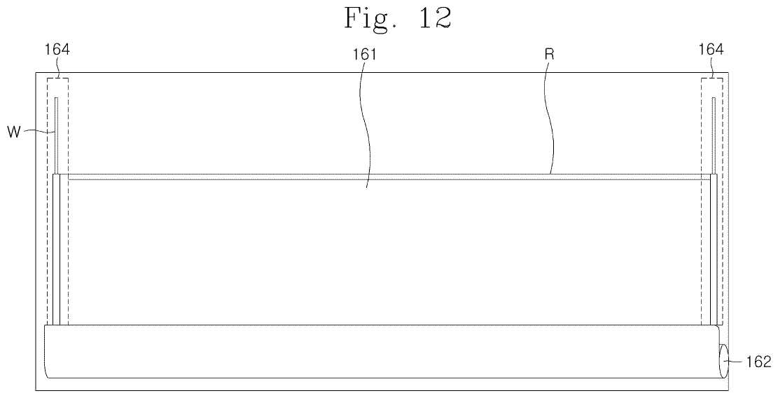

Specifically, as illustrated in FIGS. 11A, 11B, and 12, the screen controller 160 may include a fireproof screen 161, a fireproof screen case 162, a motorized opening/closing device 163, rails 164, and an operation switch 165.

The fireproof screen 161 is configured to block flames and smoke in the event of a fire and to prevent the spread of the frames and smoke, and may be made of a heat-resistant and fire-resistant material such as silica fiber, glass fiber, stainless steel, or ceramic fiber. In some embodiments, the fireproof screen 161 may be made of silica fiber so as to prevent deformation due to fire and implemented to maintain fire resistance performance for at least one hour. Here, the silica fiber may contain at least 98% SiO₂, and the fireproof screen 161 may be implemented to have a thickness of at least 0.6 mm.

The fireproof screen case 162 is configured to store the fireproof screen 161, and the fireproof screen 161 may be stored in a rolled state inside the fireproof screen case 162.

The motorized opening/closing device 163 may pull an opening/closing wire W connected to the fireproof screen 161 to deploy the fireproof screen 161 over the opening O. In this case, the opening/closing wire W may be fixed to an opening/closing bar R attached to the fireproof screen 161. Accordingly, the fireproof screen 161 may be deployed over the opening o by the operation of the motorized opening/closing device 163. Here, the opening/closing bar R may be implemented with a zinc-plated steel pipe having a thickness of at least 1.5 mm.

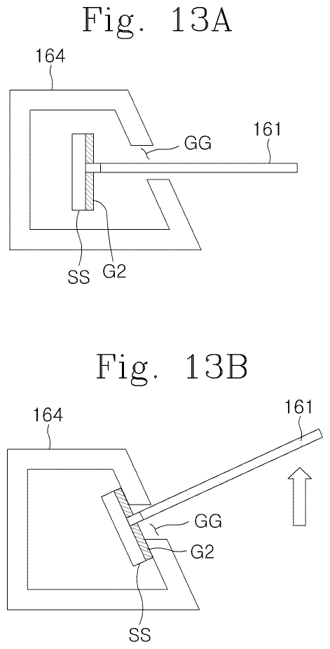

The rails 164 may be installed on a side surface of the immersion tank 110 or the like, and may guide side portions of the fireproof screen 161 during deployment. Specifically, as illustrated in FIG. 13A, the rails 164 may further include guide grooves GG into which side portions of the fireproof screen 161 are inserted and slid. In addition, the side portions of the fireproof screen 161 may further include wing portions SS configured to prevent separation from the guide grooves GG during sliding. Accordingly, the fireproof screen 161 may be stably deployed while sliding along the guide grooves GG by means of the wing portions SS.

Here, the slide surfaces in which the guide grooves GG of the rails 164 are formed may be configured to have an upward slope toward the opening O of the immersion tank 110. That is, as illustrated in FIG. 13B, when the fire extinguishing gas is supplied into the headspace HS, the fireproof screen 161 may be lifted upward by the pressure of the fire extinguishing gas. In this case, since the slide surfaces have the upward slope, the fireproof screen 161 that is lifted upward may be more stably supported.

In addition, the wing portions SS may further include sealing gaskets G2 in regions that come into contact with the slide surfaces within the guide grooves GG. That is, as illustrated in FIG. 12B, when the fireproof screen 161 is lifted by the fire extinguishing gas, the fire extinguishing gas may leak through the guide grooves GG or the like. In this case, by further providing the sealing gaskets G2 in the regions of the wing portions SS that come into contact with the slide surfaces, it is possible to enhance the sealing performance between the wing portions SS and the slide surfaces, thereby preventing leakage of the fire extinguishing gas through the guide grooves GG. Accordingly, even when the fireproof screen 161 is deployed, the fire extinguishing gas in the headspace HS may be maintained at or above the design concentration. In addition, the rails 164 may be implemented with a stainless steel material, thereby preventing corrosion caused by the coolant C or the like.

The operation switch 165 is configured to manually control the deployment of the fireproof screen 161. A worker or the like may directly make an input to the operation switch 165 as needed to deploy the fireproof screen 161.

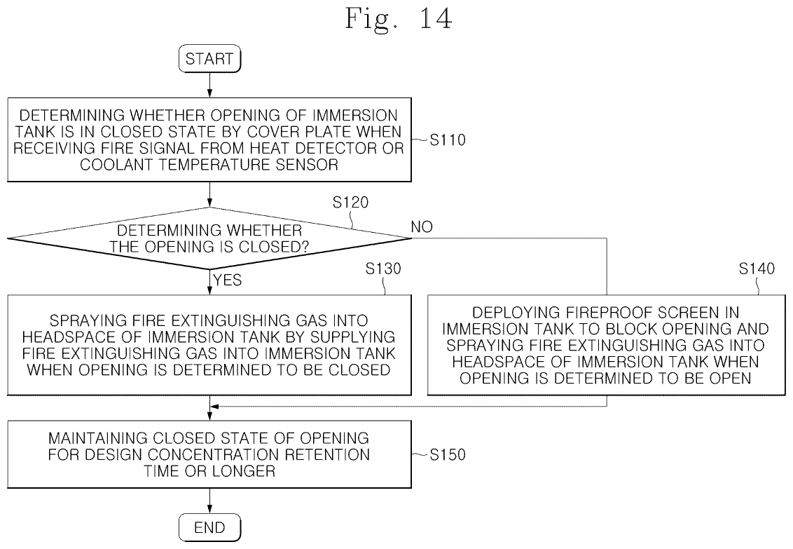

FIG. 14 is a flowchart illustrating a local automatic fire suppression method for an immersion cooling apparatus for a server according to an embodiment of the present disclosure. Here, each step in FIG. 14 may be performed by the immersion cooling apparatus for a server or by the fire extinguishing gas storage unit of the immersion cooling apparatus for a server according to an embodiment of the present disclosure. The immersion cooling apparatus for a server or the fire extinguishing gas storage unit may include a processor and a memory, and may execute the local automatic fire suppression method of the immersion cooling apparatus for a server by executing a program stored in the memory using the processor.

Referring to FIG. 14, the immersion cooling apparatus for a server may determine whether the opening of the immersion tank is in a closed state by the cover plate when receiving a fire signal from the heat detector or the coolant temperature sensor (S110). That is, when the fire signal is received, the server immersion cooling apparatus may first determine whether the opening is in a closed state, and perform corresponding control depending on whether the opening is in a closed state or in an open state.

Here, whether the opening of the immersion tank is in the closed state may be determined based on a locking monitoring signal received from the locking detection sensor. That is, since the locking detection sensor detects contact between the cover plate and the opening and generates a locking detection signal indicating whether the opening is open, the immersion cooling apparatus for a server may determine whether the opening is closed based on the locking detection signal.

Meanwhile, when receiving a fire signal, the immersion cooling apparatus for a server may stop circulation of the coolant in the immersion tank so as to prevent the spread of fire heat due to the circulation of the coolant. For example, the circulation of the coolant may be blocked by closing the valve provided in the coolant circulation pipe.

Thereafter, when it is determined that the opening is in the closed state (S120), the immersion cooling apparatus for a server may supply a fire extinguishing gas into the immersion tank and spray the fire extinguishing gas into the headspace of the immersion tank (S130). That is, since the opening is already in the closed state, the headspace is sealed by the sealing gasket provided between the opening and the cover plate. Accordingly, the immersion cooling apparatus for a server may supply the fire extinguishing gas into the headspace and maintain the fire extinguishing gas at or above a predetermined concentration.

On the other hand, when the opening is not in the closed state (S120), that is, when it is determined that the opening is open, the immersion cooling apparatus for a server may first deploy the fireproof screen in the immersion tank to block the opening. After the fireproof screen is deployed, the immersion cooling apparatus for a server may spray the fire extinguishing gas into the headspace of the immersion tank (S140).

When the opening is open, the fire extinguishing gas may not be maintained in the headspace of the immersion tank at or above the design concentration even if the gas is supplied. Therefore, the fireproof screen provided in the immersion tank may be deployed to block the opening of the immersion tank. Here, although the fireproof screen does not completely seal the immersion tank, the opening of the immersion tank may be blocked by the fireproof screen. Therefore, the fire extinguishing gas may be sprayed while the fireproof screen is in a deployed state.

Thereafter, the immersion cooling apparatus for a server may maintain the closed state of the opening for a period equal to or longer than a design concentration retention time (S150). That is, by maintaining the fire extinguishing gas at or above the design concentration for the design concentration retention time, the fire that has occurred in the coolant C may be extinguished.

The present disclosure described above may be implemented as computer-readable codes recorded on a medium. A computer-readable medium may be a medium that permanently stores a program executable by a computer or temporarily store the program for execution or downloading. The medium may include various recording or storage means in the form of a single or multiple combined hardware components, and may not be limited to media directly connected to a computer system, but may also be distributed over a network. As examples of the media, there may be a magnetic medium such as a hard disc, a floppy disc, or a magnetic tape, an optical recording medium such as a CD-ROM or a DVD, a magneto-optical medium such as a floptical disc, and media configured to store program instructions, including, for example, a ROM, a RAM, and a flash memory. In addition, examples of other media may include recording media or storage media managed by application stores that distribute applications, or by various sites, servers, or the like that provide or distribute various software. Accordingly, the above detailed description should not be interpreted as being restrictive in all respects, but rather should be considered illustrative. The scope of the present disclosure should be defined by the reasonable interpretation of the appended claims, and all modifications within the equivalent scope of the present disclosure are included within the scope of the present disclosure.

The present disclosure is not limited to the foregoing embodiments and the accompanying drawings. It will be apparent to those ordinarily skilled in the art to which the present disclosure pertains that components of the present disclosure may be substituted, modified, or changed without departing from the spirit of the present disclosure.

What is claimed is:

1. An immersion cooling apparatus for a server that performs local automatic fire suppression, the immersion cooling apparatus comprising:
an immersion tank configured to store a coolant and a server immersed in the coolant, the immersion tank having an opening for entry and exit of the server;
a cover unit comprising a cover plate configured to open or close the opening;
a heat detection unit configured to detect heat inside the immersion tank and to generate a fire signal;
a fire extinguishing gas discharging unit provided in a headspace of the immersion tank and configured to discharge the fire extinguishing gas into the immersion tank; and
a fire extinguishing gas storage unit configured to store the fire extinguishing gas and to supply the fire extinguishing gas to the fire extinguishing gas discharging unit when receiving the fire signal.

2. The immersion cooling apparatus of claim 1, wherein the cover unit further comprises a sealing gasket attached to at least one of the cover plate and the opening so as to seal the headspace of the immersion tank when closing the opening.

3. The immersion cooling apparatus of claim 1, wherein the cover plate is configured to bulge outward from the immersion tank when closing the opening, so as to guide an air flow that supplies the fire extinguishing gas to a surface of the coolant.

4. The immersion cooling apparatus of claim 3, wherein the cover plate has a cross-sectional shape selected from a group consisting of a semicircular shape, an elliptical shape, a rhomboid shape, and a triangular shape.

5. The immersion cooling apparatus of claim 1, wherein the cover unit comprises:
a locking unit configured to fix the cover plate so as to maintain a closed state of the opening; and
a locking detection sensor configured to detect contact between the cover plate and the opening in the locking unit and to generate a locking monitoring signal indicating whether the opening is open.

6. The immersion cooling apparatus of claim 1, wherein the cover unit further comprises an overpressure relief port configured to automatically open the cover plate when a set pressure or higher is applied.

7. The immersion cooling apparatus of claim 1, wherein the heat detection unit comprises at least two differential heat detectors installed on an inner surface of the cover plate.

8. The immersion cooling apparatus of claim 7, wherein the heat detection unit further comprises:
a flexible conduit provided on an outer surface of the cover plate and connected to the differential heat detectors, the flexible conduit being configured to protect a signal line that transmits the fire signal; and
a leakage prevention packing positioned between the differential heat detectors and the inner surface of the cover plate and configured to prevent leakage of the coolant.

9. The immersion cooling apparatus of claim 1, wherein the fire extinguishing gas discharging unit is provided in a column shape extending horizontally along a side surface of the immersion tank, at least opposite end portions of the fire extinguishing gas discharging unit being connected to fire extinguishing gas inlet pipes to be supplied with the fire extinguishing gas from the fire extinguishing gas storage unit.

10. The immersion cooling apparatus of claim 9, wherein the fire extinguishing gas inlet pipes are connected between a supply pipe extending from the fire extinguishing gas storage unit and the fire extinguishing gas discharging unit, the fire extinguishing gas inlet pipes having a downward slope toward an interior of the immersion tank.

11. The immersion cooling apparatus of claim 9, wherein the fire extinguishing gas discharging unit further comprises a discharge hole on a lower surface thereof to discharge the coolant into the immersion tank when the coolant is introduced.

12. The immersion cooling apparatus of claim 9, wherein the fire extinguishing gas discharging unit comprises a plurality of discharge nozzles provided at set intervals in the horizontal direction, and
wherein the plurality of discharge nozzles are classified into first nozzles having outlets oriented toward a surface of the coolant and second nozzles having outlets oriented toward a side surface of the immersion tank.

13. The immersion cooling apparatus of claim 12, wherein the fire extinguishing gas discharging unit is configured such that the first nozzles and the second nozzles are alternately arranged in sequence.

14. The immersion cooling apparatus of claim 1, further comprising:
a screen controller configured to deploy a fireproof screen to block the opening when the fire signal is received while the cover plate is in an open state.

15. The immersion cooling apparatus of claim 14, wherein the screen controller comprises:
a fireproof screen;
a fireproof screen case configured to store the fireproof screen;
a motorized opening/closing device configured to pull an opening/closing wire connected to the fireproof screen to deploy the fireproof screen over the opening; and
a rail installed in the immersion tank and configured to guide a side portion of the fireproof screen when the fireproof screen is deployed.

16. The immersion cooling apparatus of claim 15, wherein the rail comprises a slide surface in which a guide groove is formed, the guide groove being configured such that the side portions of the fireproof screen are inserted and slid therein, and
wherein the slide surface has an upward slope toward the opening.

17. The immersion cooling apparatus of claim 16, wherein the side portion further comprises a wing portion configured to prevent separation from the guide groove during sliding, and
wherein the wing portion comprises a sealing gasket in a region that comes into contact with the slide surface within the guide groove.

18. A local automatic fire suppression method for an immersion cooling facility for a server, the method comprising:
when a fire signal is received from a heat detector or a coolant temperature sensor, determining whether an opening of an immersion tank is in a closed state by a cover plate;
when the opening is determined to be closed, spraying a fire extinguishing gas into a headspace of the immersion tank by supplying the fire extinguishing gas into the immersion tank; and
maintaining the closed state of the opening for a design concentration retention time or longer.

19. The method of claim 18, wherein, in the spraying of the fire extinguishing gas, when the opening is determined to be open, a fireproof screen is deployed in the immersion tank to block the opening, and the fire extinguishing gas is sprayed into the headspace of the immersion tank.

20. The method of claim 18, wherein, in the determining of whether the opening is in the closed state, circulation of the coolant in the immersion tank is stopped when the fire signal is received.
